(19) United States
(12) Patent Application Publication
(10) Pub. No.: US 2022/0073697 A1
(43) Pub. Date: Mar. 10, 2022

(54) THERMALLY CONDUCTIVE SHEET

(71) Applicant: 3M INNOVATIVE PROPERTIES COMPANY, St. Paul, MN (US)

(72) Inventor: Taehoon Noh, Gyeonggi-do (KR)

(21) Appl. No.: 17/417,807

(22) PCT Filed: Dec. 26, 2019
(86) PCT No.: PCT/IB2019/061384

§ 371 Date: Jun. 24, 2021

Related U.S. Application Data
(60) Provisional application No. 62/785,394, filed on Dec. 27, 2018.

(51) Int. Cl. C08K 3/38; C08K 3/22; C08J 5/18; H01L 23/36

(52) U.S. Cl. CPC C08K 3/38; C08K 3/22; C08J 5/18; C08J 2333/08; C08K 2003/385; C08K 2201/001; C08K 2003/2227; H01L 23/36

(57) ABSTRACT

Thermally conductive sheets are composites of a thermoplastic polymer resin and a thermally conductive powder that includes boron nitride platelets and may also include aluminum hydroxide. The thermally conductive sheet has a first major surface and a second major surface that defines an XY plane and a thickness that defines a Z direction, where the XY thermal conductivity is greater than 30 Watts per meter Kelvin (W/m K) and the thermally conductive sheet has a thermal anisotropy ratio of 8.0 or more.

### FIELD OF THE DISCLOSURE

The current disclosure relates to thermally conductive sheets that are composites of polymers and powders and electrical articles prepared with them.

### BACKGROUND

Thermally conductive sheets are sheets that are used to join heat generating electronic elements and heat sinks and are well known as a method for cooling heating elements such as semiconductor elements installed in electronic devices. With the ongoing miniaturization and high integration of electronics, requirements for thermally conductive sheets have been increasing. For example, the heat generating density of heating elements have increased because of higher integration and reduced size of electronic devices, and the thermal conductive sheets not only have to efficiently conduct heat away from the electronic elements, they have additional requirements such as long term stability when used at the high temperatures generated in recent electronic devices.

### SUMMARY

Disclosed herein are thermally conductive sheets that are composites of polymers and thermally conductive powders, electrical articles that contain the thermally conductive sheets, and methods of preparing the electrical articles. In some embodiments, the thermally conductive sheets comprise a thermoplastic polymeric resin, and a thermally conductive powder comprising boron nitride platelets. In some embodiments, the thermally conductive powder further comprises aluminum hydroxide. The thermally conductive sheet has a first major surface and a second major surface that defines an XY plane and a thickness that defines a Z direction, where the XY thermal conductivity is greater than 30 Watts per meter Kelvin (W/m K) and the thermally conductive sheet has a thermal anisotropy ratio of 8.0 or more.

Also disclosed are electrical articles. In some embodiments, the electrical articles comprise an electronic device, and a thermally conductive sheet. The thermally conductive sheet comprises a thermoplastic polymeric resin, and a thermally conductive powder comprising boron nitride platelets. The thermally conductive sheet may further comprise aluminum hydroxide. The thermally conductive sheet has a first major surface and a second major surface that defines an XY plane and a thickness that defines a Z direction, where the XY thermal conductivity is greater than 30 Watts per meter Kelvin (W/m K) and the thermally conductive sheet has a thermal anisotropy ratio of 8.0 or more. In some embodiments, the electronic device comprises a battery, in other embodiments, the electronic device comprises a phone.

Also disclosed are methods of preparing electrical articles. In some embodiments, the method of preparing an electrical article comprises preparing a thermally conductive sheet. Preparing a thermally conductive sheet comprises providing a thermoplastic resin, dissolving the thermoplastic resin in a solvent to form a thermoplastic resin solution, providing a thermally conductive powder comprising boron nitride platelets, adding the thermally conductive powder to the thermoplastic resin solution to form a coating composition, disposing the coating composition on a carrier substrate to form a layer of coating composition, drying the layer of coating composition to remove the solvent, and hot pressing the dried coating composition layer to form a thermally conductive sheet. The thermally conductive sheet has a first major surface and a second major surface that defines an XY plane and a thickness that defines a Z direction, where the XY thermal conductivity is greater than 30 Watts per meter Kelvin (W/m K) and the thermally conductive sheet has a thermal anisotropy ratio of 8.0 or more.

### BRIEF DESCRIPTION OF THE DRAWINGS

The present application may be more completely understood in consideration of the following detailed description of various embodiments of the disclosure in connection with the accompanying drawings.

FIG. 1 shows an Scanning Electron Microscopy (SEM) image of a cross-section of Comparative Example CE-1 of the present disclosure.

FIG. 2 shows an SEM image of a cross-section of Example 1 of the present disclosure.

FIG. 3 shows an SEM image of a cross-section of Example 2 of the present disclosure.

In the following description of the illustrated embodiments, reference is made to the accompanying drawings, in which is shown by way of illustration, various embodiments in which the disclosure may be practiced. It is to be understood that the embodiments may be utilized and structural changes may be made without departing from the scope of the present disclosure.

### DETAILED DESCRIPTION

Thermally conductive sheets are sheets that are used to join heat generating electronic elements and heat sinks and are well known as a method for cooling heating elements such as semiconductor elements installed in electronic devices. With the ongoing miniaturization and high integration of electronics, requirements for thermally conductive sheets have been increasing. In the heat sink industry, traditionally metals have been used as thermally conductive sheets. There are significant drawbacks to the use of metals, however. Metals can be relatively heavy and therefore are undesirable as the devices are made increasingly light weight. Additionally, metals are susceptible to corrosion. Also, and perhaps most importantly, metals not only conduct heat they also conduct electricity. Frequently, it is desirable to have a thermally conductive sheet that is also electrically insulating.

Polymeric materials such as thermoplastic materials typically are electrically insulating, but are poor thermal conductors. Therefore, composites materials that comprise thermally conductive particles dispersed within a thermoplastic matrix have been explored as alternatives to metal thermally conductive sheets. However, such composite materials have issues.

Composite sheets are three dimensional articles that are essentially planar and have a thickness. The sheet is commonly defined as having an XY plane (length and width) and the thickness is the Z direction. A common issue with composite sheets is that the thermal conductivity in the XY plane is not sufficiently high to sufficiently disperse heat. Another issue is the thermal conductivity in the Z direction, not only the amount of heat that can flow in the Z direction, but also the thermal anisotropy. As used herein, thermal anisotropy is defined by a ratio, which is described as the thermal anisotropy ratio. The thermal anisotropy ratio is calculated by the following equation:

Thermal anisotropy ratio=Thermal conductivity (XY direction)/Thermal conductivity (Z axis direction).

It is desirable for thermally conductive sheets to have a high thermal anisotropy ratio. The higher the thermal anisotropy, the better an article is at heat spreading in the planar direction. In other words, because the heat conductivity in the XY direction is much higher than in the Z direction, heat flows in the XY direction and is spread out through the thermally conductive article as one wishes for heat dissipation.

In this disclosure, composite sheets are disclosed that comprise a thermoplastic matrix and a thermally conductive powder comprising boron nitride platelets. The conductive powder may also comprise aluminum hydroxide. The composite sheets have desirable thermal conductivity in the XY direction of at least 30 W/m K (Watts per meter Kelvin) and have a thermal anisotropy ratio of 8.0 or more.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. For example, reference to “a layer” encompasses embodiments having one, two or more layers. As used in this specification and the appended claims, the term “or” is generally employed in its sense including “and/or” unless the content clearly dictates otherwise.

As used herein, the term “adjacent” refers to two layers that are proximate to another layer. Layers that are adjacent may be in direct contact with each other, or there may be an intervening layer. There is no empty space between layers that are adjacent.

The terms “room temperature” and “ambient temperature” are used interchangeably and have their conventional meaning, that is to say refer to temperature of 20-25° C.

The term “acrylic resin” refers to polymers containing acrylic or methacrylic esters of alcohols.

Disclosed herein are thermally conductive sheets, electrical articles prepared from the thermally conductive sheets, and methods of preparing the electrical articles.

In some embodiments, the thermally conductive sheet comprises a thermoplastic polymeric resin, and a thermally conductive powder comprising boron nitride platelets. The thermally conductive sheet has a first major surface and a second major surface and defines an XY plane and a thickness that defines a Z direction, wherein the XY thermal conductivity is greater than 30 Watts per meter Kelvin (W/m K) and a thermal anisotropy ratio of 8.0 or more.

The thermally conductive sheets comprise a thermally conductive powder that comprises boron nitride platelets. Boron nitride (BN) is a chemical compound that is isoelectronic and isostructural to carbon with equal composition of boron and nitrogen atoms. Boron nitride is a heat and chemically resistant refractory compound and has excellent thermal and chemical stability.

Boron nitride platelets have found use as cooling fillers. Hexagonal boron nitride is a synthetic material with a range of aspect rations from 2:1 to 30:1 and a structure similar to graphite. Unlike graphite, boron nitride is not electrically conductive.

A wide range of boron nitride platelets are suitable for use in the thermally conductive sheets of this disclosure. Particularly suitable are the 3M Boron Nitride Cooling Filler Platelets commercially available from 3M Company, St. Paul, Minn. In some embodiments, the thermally conductive sheets of this disclosure comprise a relatively large platelet size BN material such as Platelet 0040 with an average size of 40 micrometers.

In some embodiments, the thermally conductive powder further comprises aluminum hydroxide. A wide range of aluminum hydroxide powders are suitable for use in the thermally conductive sheets of this disclosure. Particularly suitable are fine aluminum hydroxide powders with an average particle size of 20 micrometers or less, such as the 17 micrometers average particle size aluminum hydroxide powder KH-17R commercially available from KC Corporation, Seoul, Korea.

A wide range of compositional mixtures of boron nitride platelets and aluminum hydroxide are suitable. In some embodiments, the thermally conductive powder comprises at least 50% by weight boron nitride platelets. In other embodiments, the boron nitride platelets and aluminum hydroxide are present in equal amounts by weight.

The thermally conductive sheet also comprises a thermoplastic polymeric resin. The thermoplastic polymeric resin serves as a binder matrix to hold the thermally conductive sheet together. A wide range of thermoplastic polymeric resins are suitable. In some embodiments, the thermoplastic polymeric resin comprises an acrylic resin. A wide range of acrylic resins are suitable. It has been found desirable to prepare a solution of the acrylic resin in an organic solvent, so it is desirable that the acrylic resin be soluble in organic solvents. Examples of suitable organic solvents includes esters such as ethyl acetate, ketones such as acetone and MEK (methyl ethyl ketone), ethers such as ethyl ether and tetrahydrofuran (THF), hydrocarbons including aromatics such as benzene, toluene, and aliphatics such as petroleum ether and hexanes. Ethyl acetate and MEK are particularly suitable solvents.

In some embodiments, it is desirable that the acrylic resin be of a relatively high molecular weight and have a low solution viscosity. In some embodiments, the acrylic resin has a Mw (weight average molecular weight) of 3.5×10⁵ grams/mole or higher and a solution viscosity of 1,000 mPa s (milliPascal seconds) or less. Among the particularly suitable thermoplastic acrylic resins are those sold under the trade name “TEISANRESIN” by Nagase Chemtex Corporation, Tokyo, Japan. An example of a suitable thermoplastic acrylic resin is TEISANRESIN SG-80H.

A range of compositions for the thermally conductive sheet are suitable. In some embodiments, the thermally conductive sheet comprises 100 parts by weight thermoplastic polymeric resin, and 80 parts by weight thermally conductive powder. In some particularly suitable embodiments, the thermally conductive powder comprises 40 parts by weight boron nitride platelets and 40 parts by weight aluminum hydroxide.

The thermally conductive sheet may have a wide range of thicknesses depending upon the desired use for the sheet. In some lightweight electronic devices such as phones, the thickness is suitably thin. In some of these embodiments, the sheet has a thickness of 200 micrometers or less. In other larger electronic articles such as batteries, the thickness is suitably thick. In some of these embodiments, the sheet has a thickness of 0.5 millimeters or greater.

Also disclosed herein are electrical articles that incorporate the thermally conductive sheets described above. In some embodiments, the electrical article comprises an electronic device, and a thermally conductive sheet, where the thermally conductive sheet comprises a thermoplastic polymeric resin, and a thermally conductive powder comprising boron nitride platelets. As described above, the thermally conductive sheet has a first major surface and a second major surface and defines an XY plane and a thickness that defines a Z direction, wherein the XY thermal conductivity is greater than 30 Watts per meter Kelvin (W/m K) and a thermal anisotropy ratio of 8.0 or more.

A wide variety of electrical articles can be made that utilize the thermally conductive sheets of this disclosure. A wide range of devices that generate heat that must be dissipated can utilize these thermally conductive sheets. The high thermal conductivity and low electrical conductivity of the sheets makes them particularly suitable. The size and thickness of the sheets utilized can vary widely depending upon the article to be prepared. In lightweight articles such as phones, the thickness is suitably thin. In some of these embodiments, the sheet has a thickness of 200 micrometers or less. In other larger electronic articles such as batteries, the thickness is suitably thick. In some of these embodiments, the sheet has a thickness of 0.5 millimeters or greater.

Also disclosed are methods of preparing electrical articles. These methods comprise preparing a thermally conductive sheet and disposing the thermally conductive in an electronic device. In some embodiments, preparing a thermally conductive sheet comprises providing a thermoplastic resin, dissolving the thermoplastic resin in a solvent to form a thermoplastic resin solution, providing a thermally conductive powder comprising boron nitride platelets, adding the thermally conductive powder to the thermoplastic resin solution to form a coating composition, disposing the coating composition on a carrier substrate to form a layer of coating composition, drying the layer of coating composition to remove the solvent, and hot pressing the dried coating composition layer to form the thermally conductive sheet. The desirable properties of these thermally conductive sheets are described in detail above.

In some embodiments, the thermally conductive powder further comprises aluminum hydroxide. As mentioned above, in some embodiments, the thermally conductive powder comprises at least 50% by weight boron nitride platelets. In other embodiments, the thermally conductive powder contains equal amounts by weight of boron nitride platelets and aluminum hydroxide.

Suitable thermoplastic polymeric resins are described above. Typically, the thermoplastic polymeric resin comprises an acrylic resin.

The drying step is typically carried out at an elevated temperature. Depending upon the solvent used, the temperature and drying time can vary. In some embodiments, the solvent is ethyl acetate and drying is carried out by passing the coating through a 100° C. oven.

The hot pressing step can be carried out using conventional hot press equipment. Without wishing to be bound by theory, it is believed that the hot pressing step helps to densify the composite material and increase the thermal flow in the XY direction and the thermal anisotropy ratio. Typically, the hot pressing is carried out a temperature of 150° C. for 1 hour or longer.

As mentioned above, the sheet can have a wide range of thicknesses. In some embodiments, the sheet has a thickness of 200 micrometers or less. In other embodiments, the sheet has a thickness of 0.5 millimeters or greater.

The method further comprises contacting the thermally conductive sheet to an electronic device. As mentioned above, a wide range of electronic devices are suitable. In some embodiments, the electronic device comprises a phone or components of a phone, in other embodiments, the electronic device comprises a battery.

### Examples

Objects and advantages of this disclosure are further illustrated by the following comparative and illustrative examples. Unless otherwise noted, all parts, percentages, ratios, etc. in the examples and the rest of the specification are by weight, and all reagents used in the examples were obtained, or are available, from general chemical suppliers such as, for example, Sigma-Aldrich Corp., Saint Louis, Mo., US or may be synthesized by conventional methods.

The following abbreviations are used herein: mm=millimeters; cm=centimeters; in =inches; s=seconds; g=grams; J=Joules; mPa·s=millipascal seconds; K=Kelvin; ° C.=degrees Celsius; W/(m K)=Watts per meter Kelvin. The terms “wt %” and “% by weight” are used interchangeably and refer to the parts by weight of a solid component per 100 parts total weight of the composition.

TABLE 1
Materials

| Material | | |
|---|---|---|
| (Product | | |
| Name from | | |
| Manufacturer) | Description | Source |
| Acrylic Resin | High Molecular Weight | Nagase Chemtex, |
| | Thermoplastic Acrylic | Tokyo, Japan |
| | Resin commercially | |
| | available as | |
| | “TEISANRESIN SG-80H” | |
| | with a Mw = 35 × 10⁴ | |
| | g/mole, and Viscosity | |
| | 1000 mPa · s | |
| BN Platelets | Large Platelet BN Powder | 3M Company, Saint |
| | of platelet grade “Platelet | Paul, MN, US |
| | 0040” with a platelet | |
| | size = 40 micrometers | |
| Aluminum | Fine aluminum hydroxide | KC Corporation, |
| Hydroxide | powder commercially | Seoul, Korea |
| | available as “KH-17R” | |
| | (Dp50 = 17 micrometers) | |

### Sample Preparation

To prepare Examples 1 and 2 and Comparative Example CE1, inorganic powders were combined with ethyl acetate solvent, then the polymer resin was added to the mixture. Compositions are provided in Table 2.

TABLE 2
Compositions

| | Example 1 | Example 2 | CE1 |
|---|---|---|---|
| Acrylic Resin (solid | 100 | 100 | 100 |
| content 18% by weight), g | | | |
| Aluminum Hydroxide, g | | 40 | 80 |
| BN Platelets, g | 80 | 40 | |
| Filler Loading (wt %)^{§} | 81.63 | 81.63 | 81.63 |

^{§}(total weight of filler)/(total weight of polymer resin and fillers)

Mixtures were coated onto a process liner using a coating roll and passed through an oven at a temperature of approximately 100° C. The sheets were then pressed in a hot press at 150° C. for 1 hour to achieve higher density.

### Test Methods

Thermal conductivity measurements were conducted using ASTM E1461-13 “Standard Test Method for Thermal Diffusivity by the Flash Method.” Disks having 25.4 mm (1 in) diameter and 0.5 mm thickness were punched out of a cured sample prepared as described above. Thermal diffusivity, α(T), was measured using an LFA-447 HYPERFLASH Light Flash Apparatus from Netzsch Instruments of Burlington, Mass., US. Thermal conductivity, k, was calculated from thermal diffusivity, heat capacity, and density measurements according the formula: k=α·Cₚ·ρ where k is the thermal conductivity in W/(m K), α is the thermal diffusivity in mm²/s, Cₚ is the specific heat capacity in J/K-g, and ρ is the density in g/cm³. Specific heat capacity, Cₚ, was determined using Differential Scanning calorimetry (DSC.)

Scanning Electron Microscopy (SEM) images were obtained using a JSM-5600LV, JEOL, Japan.

### Results

Thermal properties are summarized in Table 3. The thermal anisotropy ratio was calculated by the following equation:

Thermal anisotropy ratio=Thermal conductivity (XY direction)/Thermal conductivity (Z axis direction).

Examples 1 and 2 showed high thermal conductivity along the XY direction and a high thermal anisotropy ratio in comparison to CE1, which is interpreted to indicate that the materials of the present disclosure will provide good heat spreading property along plane direction.

TABLE 3
Thermal Properties

| Property | Unit | Example 1 | Example 2 | CE1 |
|---|---|---|---|---|
| Density, ρ | g/cm³ | 1.45 | 1.50 | 1.84 |
| Cₚ | J/g/K | 1.45 | 1.87 | 2.13 |
| Thermal diffusivity (XY) | mm²/s | 17.7 | 8.0 | 1.7 |
| Thermal diffusivity (Z) | mm²/s | 0.69 | 0.97 | 0.63 |
| Thermal conductivity (XY) | W/(m-K) | 37.3 | 22.6 | 6.8 |
| Thermal conductivity (Z) | W/(m-K) | 1.5 | 2.7 | 2.5 |
| Thermal Anisotropy Ratio | | 25.65 | 8.29 | 2.77 |

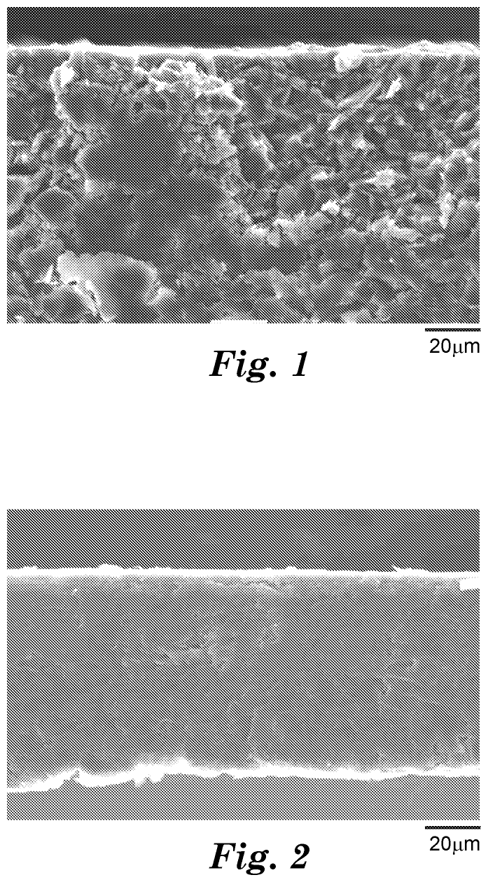

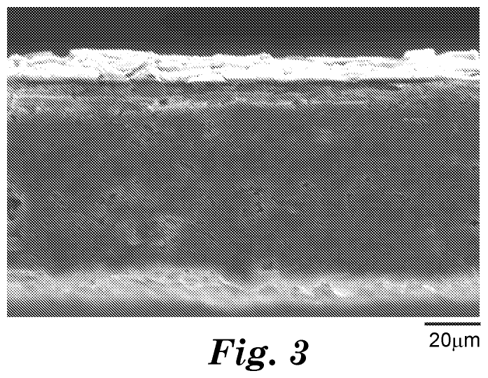

Cross sectional SEM images (FIGS. 2 and 3) demonstrated that Examples 1 and 2 had a highly densified structure, with minimal voids, in comparison to CE1 (FIG. 1), which shows voids and cracks. This densification results in high thermal conductivity along the XY plane direction for Examples 1 and 2.

Various modifications and alterations to this disclosure will become apparent to those skilled in the art without departing from the scope and spirit of this disclosure. It should be understood that this disclosure is not intended to be unduly limited by the illustrative embodiments and examples set forth herein and that such examples and embodiments are presented by way of example only with the scope of the disclosure intended to be limited only by the claims set forth herein as follows.

What is claimed is:

1. A thermally conductive sheet comprising:
a thermoplastic polymeric resin; and
a thermally conductive powder comprising boron nitride platelets, wherein the thermally conductive sheet has a first major surface and a second major surface that defines an XY plane and a thickness that defines a Z direction, wherein the XY thermal conductivity is greater than 30 Watts per meter Kelvin (W/m K) and has a thermal anisotropy ratio of 8.0 or more.

2. The thermally conductive sheet of claim 1, wherein the thermally conductive powder further comprises aluminum hydroxide.

3. The thermally conductive sheet of claim 2, wherein the thermally conductive powder comprises at least 50% by weight boron nitride platelets.

4. The thermally conductive sheet of claim 1, comprising 100 parts by weight thermoplastic polymeric resin, and 80 parts by weight thermally conductive powder.

5. The thermally conductive sheet of claim 4, wherein the 80 parts by weight of thermally conductive powder comprises 40 parts by weight boron nitride platelets and 40 parts by weight aluminum hydroxide.

6. The thermally conductive sheet of claim 1, wherein the thermoplastic polymeric resin comprises an acrylic resin.

7. The thermally conductive sheet of claim 1, wherein the sheet has a thickness of 200 micrometers or less.

8. The thermally conductive sheet of claim 1, wherein the sheet has a thickness of 0.5 millimeters or greater.

9. An electrical article comprising:
an electronic device; and
a thermally conductive sheet comprising:
a thermoplastic polymeric resin; and
a thermally conductive powder comprising boron nitride platelets, wherein the
thermally conductive sheet has a first major surface and a second major surface
that defines an XY plane and a thickness that defines a Z direction, wherein the
XY thermal conductivity is greater than 30 Watts per meter Kelvin (W/m K)
and has a thermal anisotropy ratio of 8.0 or more.

10. The electrical article of claim 9, wherein the thermally conductive powder further comprises aluminum hydroxide.

11. The electrical article of claim 9, wherein the electronic device comprises a battery, and the thermally conductive sheet has a thickness of 0.5 millimeters or greater.

12. The electrical article of claim 9, wherein the electronic device comprises a phone and the thermally conductive sheet has a thickness of 200 micrometers or less.

13. The method of preparing an electrical article comprising:
preparing a thermally conductive sheet, wherein preparing a thermally conductive sheet comprises:
providing a thermoplastic resin;
dissolving the thermoplastic resin in a solvent to form a thermoplastic resin solution;
providing a thermally conductive powder comprising boron nitride platelets;
adding the thermally conductive powder to the thermoplastic resin solution to form a
coating composition;
disposing the coating composition on a carrier substrate to form a layer of coating composition;
drying the layer of coating composition to remove the solvent;
hot pressing the dried coating composition layer to form a thermally conductive sheet,
wherein the thermally conductive sheet has a first major surface and a second major
surface that defines an XY plane and a thickness that defines a Z direction, wherein the
XY thermal conductivity is greater than 30 Watts per meter Kelvin (W/m K) and has a
thermal anisotropy ratio of 8.0 or more.

14. The method of claim 13, wherein the thermally conductive powder further comprises aluminum hydroxide.

15. The method of claim 14, wherein the thermally conductive powder comprises at least 50% by weight boron nitride platelets.

16. The method of claim 13, wherein the thermoplastic polymeric resin comprises an acrylic resin.

17. The method of claim 13, wherein the sheet has a thickness of 200 micrometers or less.

18. The method of claim 13, wherein the sheet has a thickness of 0.5 millimeters or greater.

19. The method of claim 13, wherein the carrier substrate comprises a removable film substrate.

20. The method of claim 13, wherein the method further comprises contacting the thermally conductive sheet to an electronic device.
